(19) United States
(12) Patent Application Publication
(10) Pub. No.: US 2010/0288554 A1
(43) Pub. Date: Nov. 18, 2010

(54) UNIVERSAL ADJUSTABLE SUPPORT BRACKET FOR ELECTRICAL JUNCTION BOXES

(76) Inventor: Afshin Jafari, (US)

Correspondence Address: Afshin Jafari, 1816 Harriman Lane, Redondo Beach, CA, 90278, US

(21) Appl. No.: 12/779,910

(22) Filed: May 13, 2010

Related U.S. Application Data
(60) Provisional application No. 61/178,450, filed on May 14, 2009.

(51) Int. Cl. H05K 7/14

(52) U.S. Cl. 174/545

(57) ABSTRACT

The present invention is a set of universal support brackets that attach to the side surface of an electrical box and support the box against the inside surface of the opposing wall boards. Moreover, the invention adapts to most electrical steel boxes with any depths, and provides support in hollow wall structures of different depths. After attachment to the electrical junction box, the universal support bracket extends against the back wall surface to prevent the box from being pushed into the hollow space between wall boards; effectively securing the box in place. The brackets are adjustable, and consist of either two or three components, incorporating a ratchet or locking mechanism. The bracket provides small intervals to effectively accommodate the adjustment of numerous sizes of electrical outlet boxes with a variety of hollow wall depths. Mounting and adjustment of the bracket takes only a few seconds.

### CROSS-REFERENCE TO RELATED APPLICATION

This patent application claims the benefit of the filing date of U.S. Provisional Patent Application Ser. No. 61/178.450, filed May 14, 2009 and entitled “ADJUSTABLE SUPPORT BRACKET FOR STEEL ELECTRICAL JUNCTION BOX”, the entire content of which is hereby expressly incorporated by reference.

### FIELD OF THE INVENTION

The inventions described below relate to the field of electrical construction components and more specifically they clip on the edge of the electrical junction box or to the side plate of the electrical junction box providing stability for the box inside the hollow wall structure.

### BACKGROUND

Modern light-frame interior structures usually consist of a stud skeleton gaining strength from rigid panels or wall boards attached to both sides of the stud frame, the stud frames being structured using either metal studs or wood studs. The electrical junction boxes are installed inside the hollow wall. Mostly the boxes are secured to the structure by screwing one side of them to the stud, however the installation does not provide sufficient rigidity and the electrical junction box may still be loose. To be more precise, the outlet. box has to be restrained from moving inwards towards the depth of the hollow wall. If the rear support on the back of the box is loose or insufficient, it will not hold the outlet box securely when either pushing a plug in or pulling it out of the outlet box.

The rigidity of the box is usually achieved by putting customized support behind the back plate of the outlet or junction box. Installers tend to make the back support out of wood or steel material and the supports are mostly fabricated in the field. Although this resolves the inward movement of the outlet box, it is costly and very time consuming especially when it comes to projects of larger scale.

Another way to achieve this is using steel brackets that are currently available in the market. One of the most successful designs is a bracket with pre-stamped bend lines which can be bent parallel to the back plate of the box on the opposite panel wall disclosed in U.S. Pat. No. 4,978,092 to Nattel. There are many restrictions that make the use of these said brackets difficult, one example being the interval of the scored bend lines across the bracket strip, which don't offer well tuned adjustment for the distance between the box and the opposite panel on which the rest. If to provide the fine tuning the bend lines are stamped in shorter intervals, it makes the steel brackets structurally weak and they cannot function. Another problem is that most manufacturers integrate the support brackets into the electrical junction box body, and this integration forces the electrical technicians to rely on a specific brand of the box. If offered separately, they require a separate installation onto the outlet box, and such installation will require a time consuming drilling process that will also mark up overall expected cost.

### SUMMARY

In some embodiments, the present invention is a set of universal support brackets that attach to the side surface of an electrical box to support the box against the inside surface of the opposite wall board. Moreover, the invention adapts to most electrical steel boxes with any depth, and provides support in hollow wall structures of different depths. The present invention mounts on the side of the box opposite from the stud attachment. It extends against the back wall surface to prevent the box being pushed into the hollow space. In most cases, a plaster ring is installed on the box with an opening for electrical devices. The walls are then cut according to the opening area of the plaster rings covering the peripheral area of the plaster ring and the box. This setup prevents the boxes being pulled out of the wall. For configurations where the support brackets must restrain the movements in both directions, the invention provides a secured installment against the wall surface by screwing the bracket end in to the wall surface to restrain outward movement of the box.

In some embodiments, the present invention can be attached to the steel outlet box through a pair of holes on each side of the steel outlet box or it can be simply clipped to the edge of the box. According to one embodiment, the present invention is consisted of two or more parts forming a ratchet mechanism. One embodiment of the present invention consists of a Stationary Base Plate that attaches to the side of a junction box, and a sliding extension that slides inside or outside of the Stationary Base Plate; extending to the desired depth. At the other end where it sits against the opposing inner surface of the wall, it may have a combination of barbs to grip on the inner wall surface. Ratchet openings (steps) can be cutout on any of the members (sliding part or Stationary Base Plate) depending on the design configuration. A third feature is a retractable spring that can be either mounted on either member (the one without the cutouts) as a stand alone part (a third member) or it can be designed as an integrated part of the other two members. Small intervals are cut out in the ratchet mechanism to enable fine adjustment of the steel box: allowing it to be perfectly flush with the opposing wall. As an alternative, a barbed plate with a textured surface forming steps can be placed on the opposing member to the spring instead of the cutouts to achieve even finer intervals.

### BRIEF DESCRIPTION OF THE DRAWING

FIG. 1 shows an exemplary support bracket in isometric view and its application on the stud mounted steel box installed and secured against the back wall, according to some embodiments of the present invention.

FIG. 2 shows an exemplary support bracket in three standard views and one isometric view, according to some embodiments of the present invention.

FIG. 3 shows an exemplary Stationary Base Plate in three standard views and two isometric views, according to some embodiments of the present invention.

FIG. 4 shows an exemplary sliding part in three standard views and two isometric views, according to some embodiments of the present invention.

FIG. 5 shows an exemplary spring part in three standard views and two isometric views, according to some embodiments of the present invention.

FIG. 6 shows an alternative exemplary support bracket in one isometric view and its application on the stud mounted steel box installed and secured against the back wall, according to some embodiments of the present invention.

FIG. 7 shows an alternative exemplary support bracket in three standard views and two isometric views, according to some embodiments of the present invention.

FIG. 8 shows an alternative exemplary mounting base in three standard views and two isometric views, according to some embodiments of the present invention.

FIG. 9 shows an alternative exemplary Stationary Base Plate that has the spring piece integrated in three standard views and two isometric views, according to some embodiments of the present invention.

FIG. 10 shows an alternative exemplary sliding part in three standard views and two isometric views, according to some embodiments of the present invention.

FIG. 11 shows an alternative exemplary support bracket mounted on the edge of the electrical steel box in three standard views and one isometric view, according to some embodiments of the present invention.

FIG. 12 shows an alternative exemplary support bracket mounted on the edge and side plate of the electrical steel box in two isometric views, according to some embodiments of the present invention.

### DETAIL DESCRIPTION

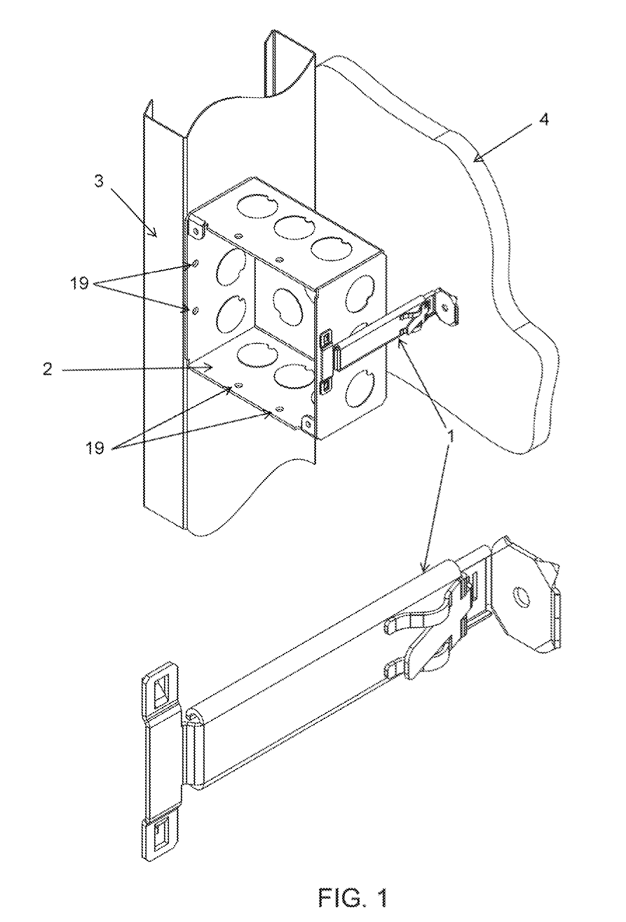

A three member ratchet mechanism is depicted in FIG. 1 as one embodiment of the invention. The support bracket 1 is mounted on the steel box 2. The box is attached to the stud 3 by means of screws, nails or mounting brackets (not shown). The sliding part 7 of the support bracket 1 is then extended all the way to sit against back wall 4.

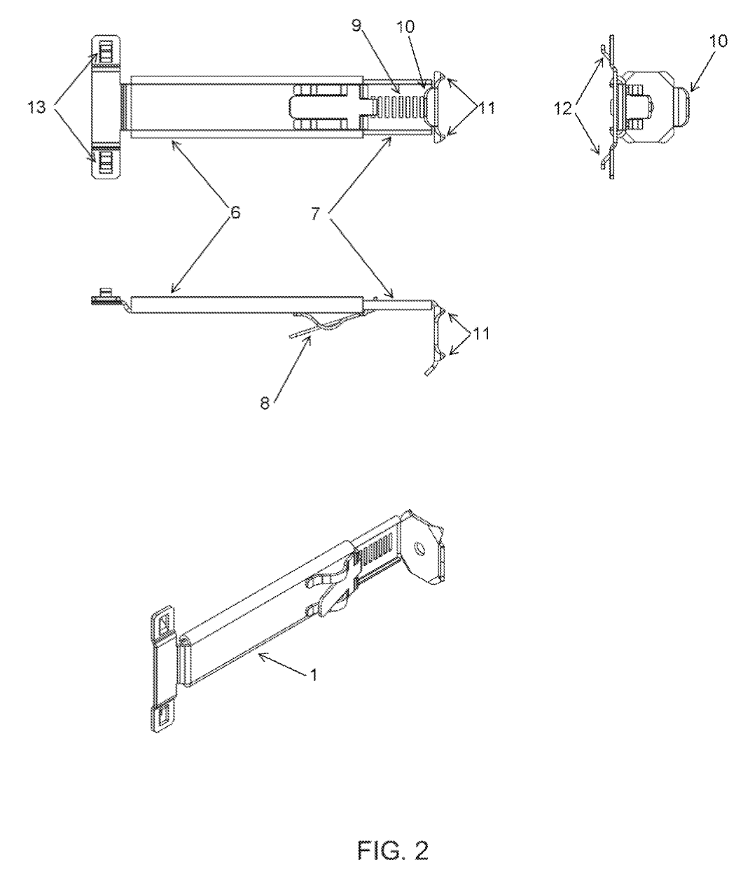

FIG. 2 shows support bracket 1 assembly which is consisted of three members; Stationary Base Plate 6, sliding part 7, and spring 8.

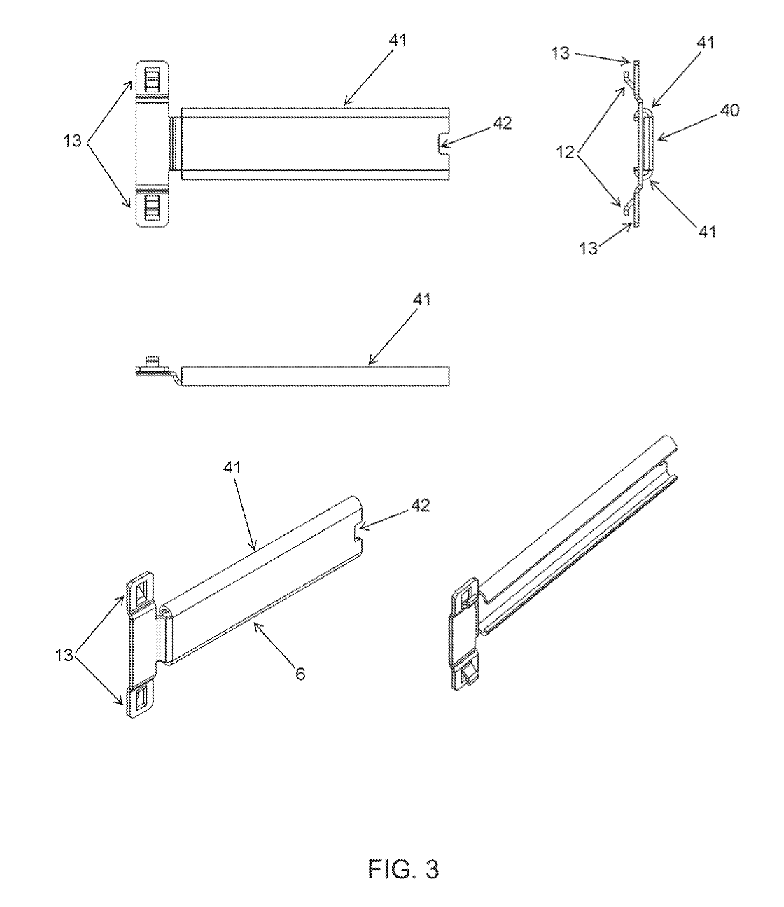

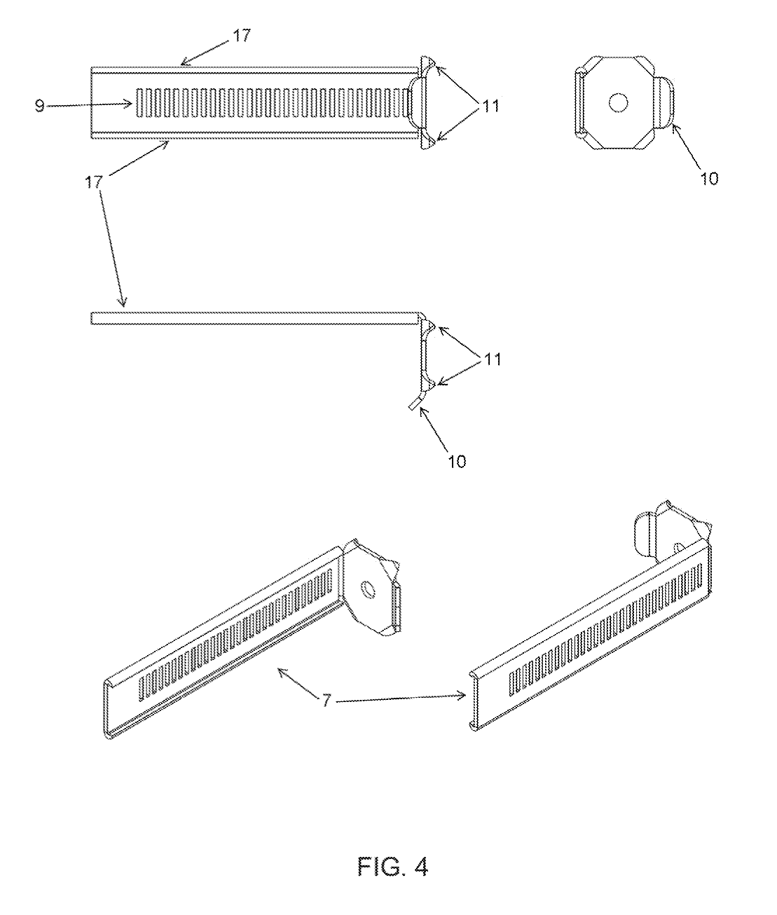

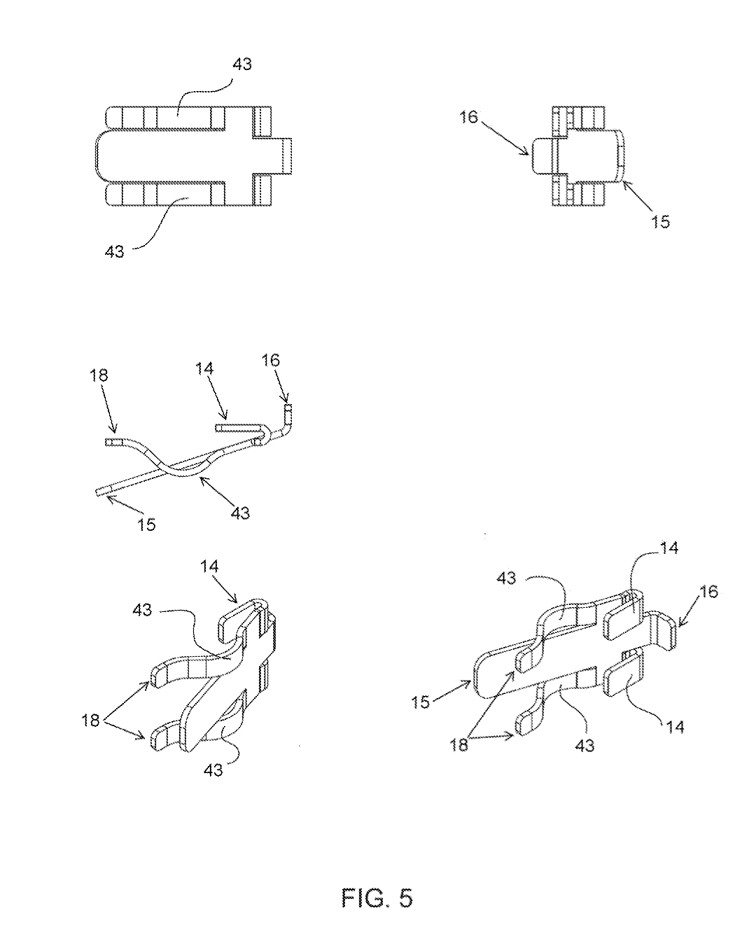

Stationary Base Plate 6 is made of a T shape spring steel or steel sheet metal. In FIG. 3 the T ends 13 have two offset tabs 12 that engage in steel box side holes 19 shown in FIG. 1. The two longitudinal sides of the T strip 40 are bent inward to create a sliding guide 41 for the sliding part 7. The other end of the T strip 40 may have a cutout area 42 to accommodate a better fit and function for spring 8.
The sliding part 7, shown in FIG. 4 is made of steel metal sheet or similar material. It is consisted of an elongate strip of sheet metal with one end at a right angel where it sits against the back wall 4. Four corners of the 90 degree angled end can be bent outward to make four barbs 11 for a better grip into the back wall 4. The side part of the 90 degree angled end is also bent inward to make tab 10 for pushing the sliding part 7 in and out. Two longitudinal sides of the elongate strip are bent to make guiding curves 17 matching the stationary guides 41 of Stationary Base Plate 6. A number of cutouts 9 are perforated on the elongate strip that makes the adjustable steps of the support bracket. The angled protrusion or locking latch 16 of spring 8 shown in FIG. 5 is locked in the perforated area 9 notches and locks the mechanism.

FIG. 5 shows the spring 8 which is stamped out of spring steel. It forms a pair of clips 14 where it mounts on the sliding part. The spring plate is sitting in a preloaded position in about 10 to 50 degree angle with respect to the Stationary Base Plate surface 6. It also has two tabs 18 that function as the lever pivots and are connected to the spring plate via two curved surfaces 43. One tab 15 in between the pivot tabs 18 is extended along the main angled plate of the spring. The area between the clips 14 is bent perpendicular to the Stationary Base Plate 6 to form a locking latch 16. To release the mechanism from lock position, the tab 15 is pushed down towards the Stationary Base Plate 6 which in turns lifts the locking latch 16 and releases the sliding part 7 from locking position.

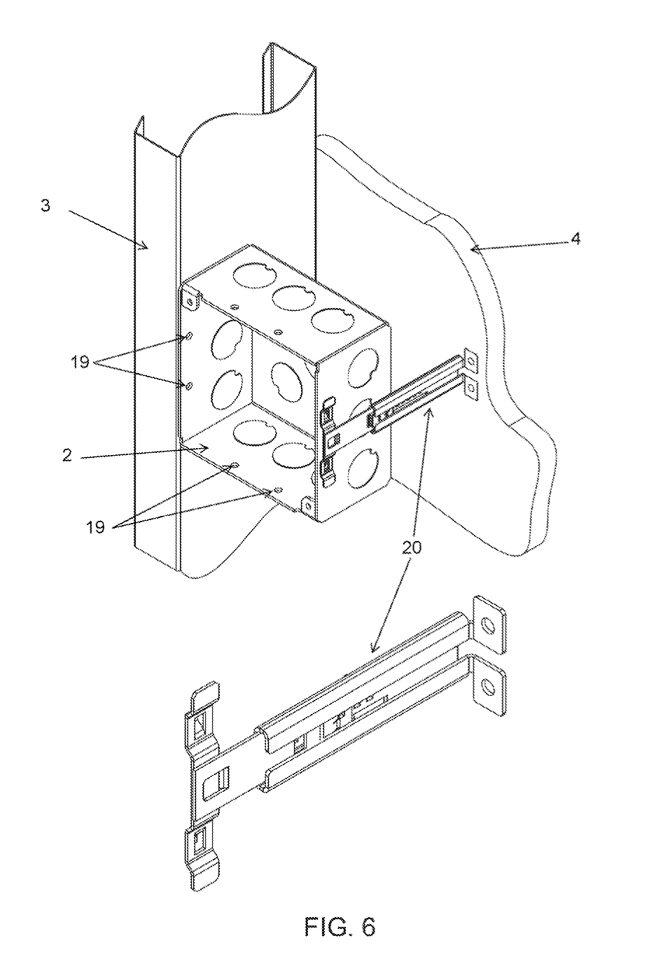

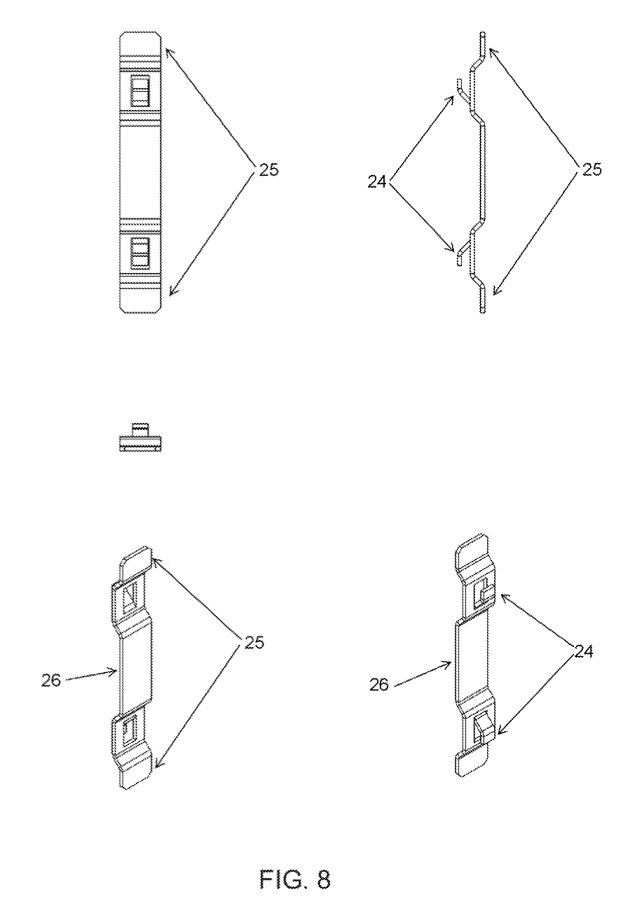

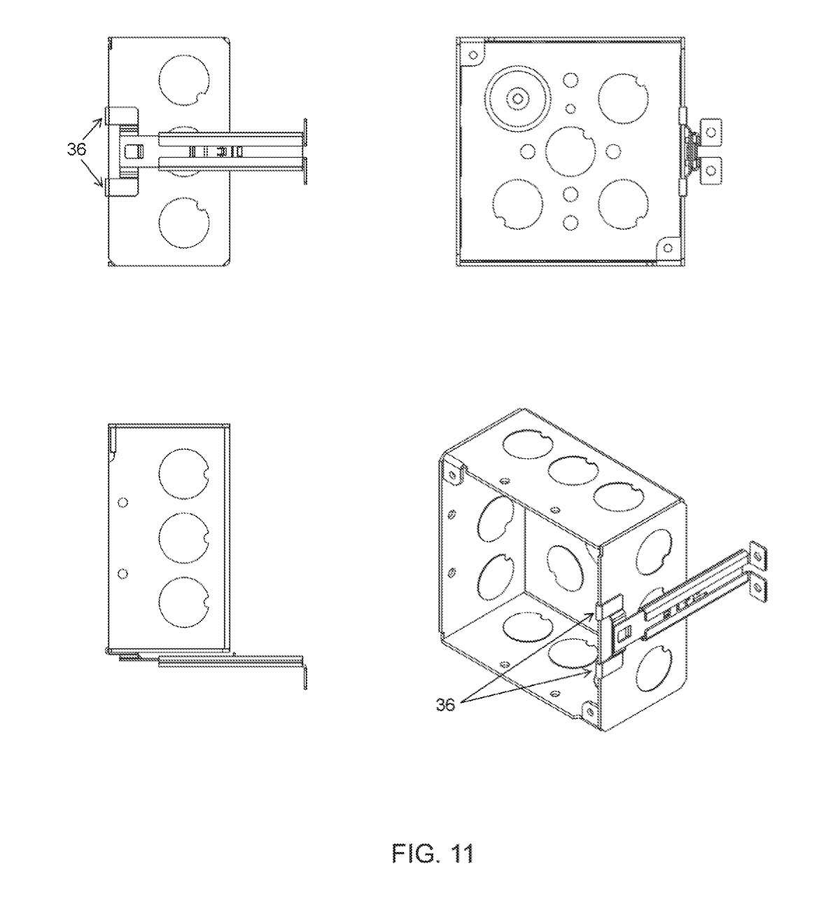

FIG. 6 shows an alternative design of the support bracket 20, according to some embodiments of the present invention. The subject support bracket 20 employs a spring steel base clip plate 21 that clamps on the steel box 2 by means of engaging the two angled tabs 24 into the box holes 19 shown in FIG. 6 when the end tabs 25 of the base clip plate 21 are pushed towards one another. See FIG. 8. It can be alternatively clipped on the edge of the steel box 2 via two alternative clips 36 on base clip plate 21. This configuration is shown in FIG. 11. The Stationary Base Plate 22 is attached, hinged on the middle plane 26 of the base clip plate 21.

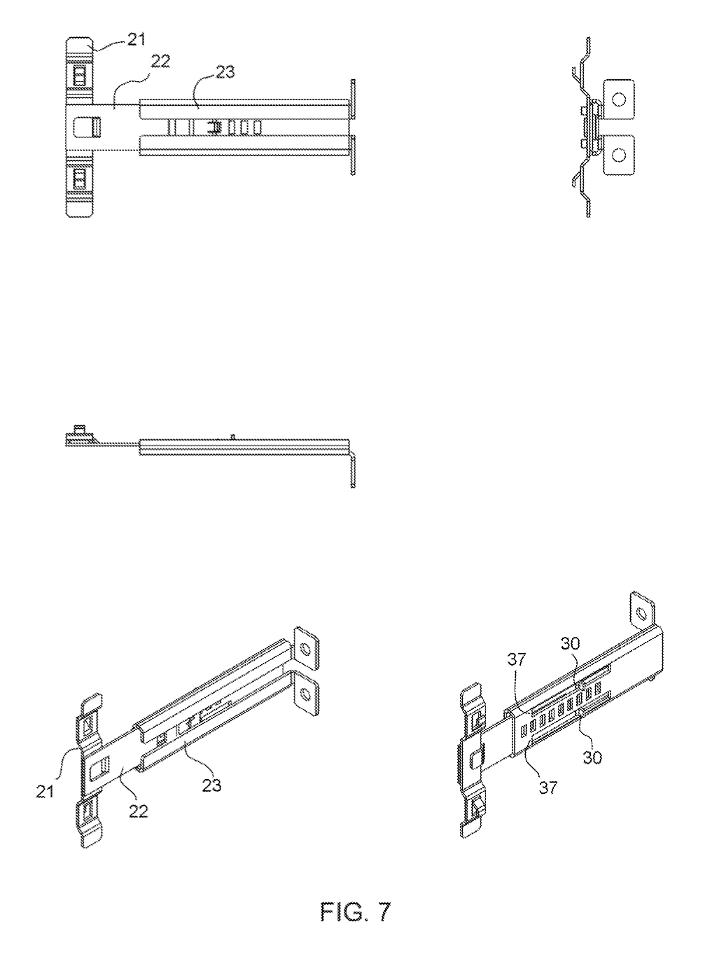

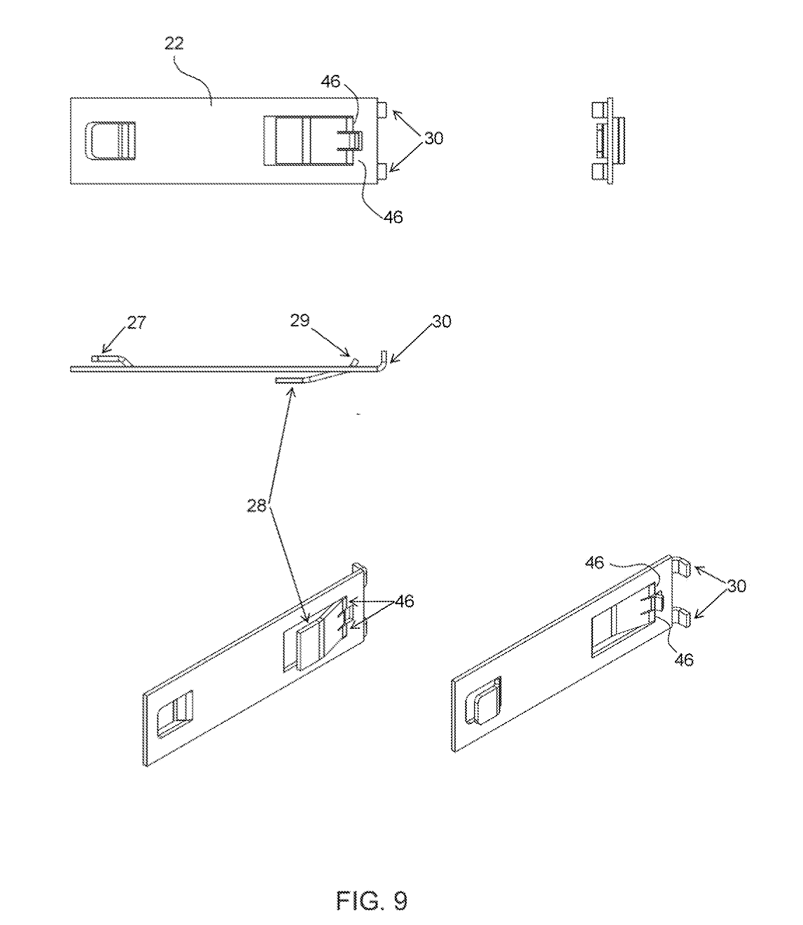

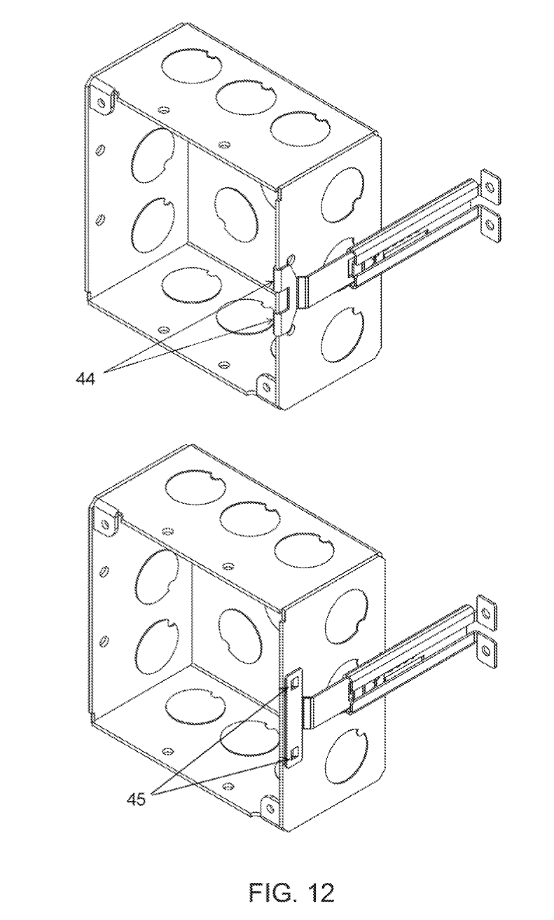

In some embodiments of the present invention the base clip plate 21 can be fabricated as part of the Stationary Base Plate 22 to form one piece. This configuration will only have two components; Stationary Base Plate 22 and sliding part 23 that it is shown in FIG. 12. The Stationary Base Plate 22 can be either mounted on the edge of the outlet box 44, or it clamped on the outlet box 2 by means of engaging the clip tabs 45 through the holes 19 of the outlet box 2. The spring component of the previous embodiment of the present invention is embedded in the Stationary Base Plate 22 in this configuration.
FIG. 7 shows the three parts; the base clip plate 21, the Stationary Base Plate 22, and the sliding part 23 in retracted position.
FIG. 8 shows the base clip plate 21 which is symmetrically jog-bent on both ends providing two tabs 25 that can be bent to engage the two protruded tabs 24 in to the steel box side holes 19. In some embodiments of the present invention, the base clip plate 21 will just be attached by pressing the tabs 24 in to the side holes 19 of the outlet box 2. The middle flat area 26 of the base clip plate 21 is used for attaching the spring/Stationary Base Plate 22 by clipping it on through the extruded tab 27 as shown in FIG. 9.

FIG. 9 shows the spring/Stationary Base Plate 22 which integrates the two components into one part that is consisted of a flat strip of spring steel. The tab 27 is stamped out close to one end of the plate and it is used to mount the part 22 on the base clip plate 21 middle flat area 26. On the other end two tabs 30 are bent at an angle to act as stopper when the mechanism is pushed down. They give the whole assembly two support points against the steel box 2 side wall when the spring tab 28 is pushed down to unlock the ratchet latch 29. The area between the two tabs 30 is cutout to permit free movement of the sliding component 23. The locking latch 29 is cutout off the flat strip of Stationary Base Plate 22 and it is only attached to it via two sections 46. The larger area of the cutout section is offset outwards at an angle ranging from 10° to 80° to make the spring tab 28. The smaller side of the cutout between the two attaching sections 46 is bent inward at an arbitrary angle between 10° to 170° to make the ratchet latch 29. The angle of the locking latch 29 shown in FIG. 9 is set to 60° with respect to the flat strip 22. The latch 29 engages in the cutouts 33 of the sliding part 23.

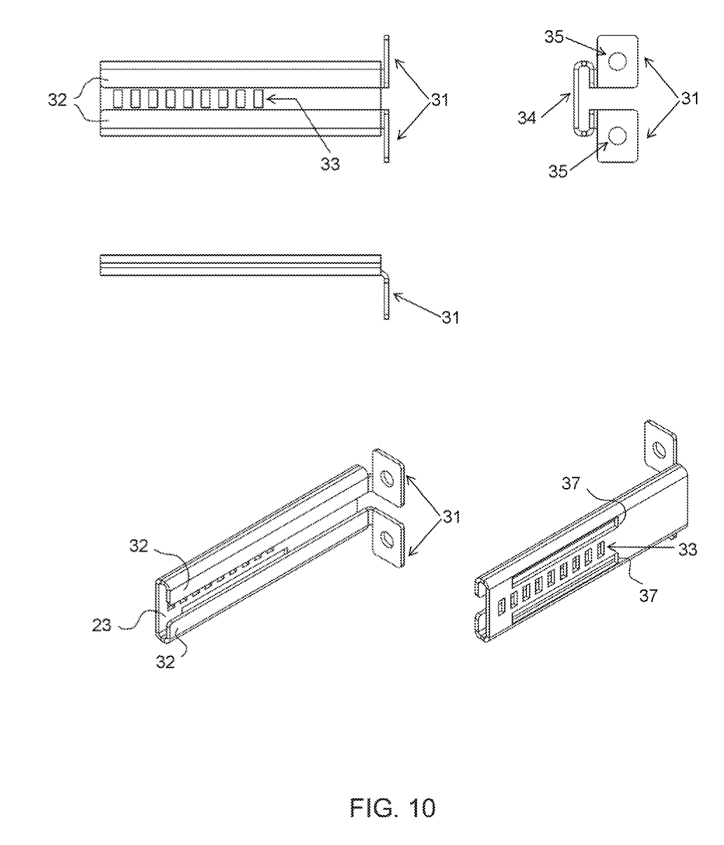

FIG. 10 shows the sliding part 23 which consists of a flat plate 34 of steel sheet metal. The two longitudinal edges 32 of the plate 34 are hemmed to enclose the part 22 in FIG. 9. Two guiding openings 37 are cutout along the hems 32 longwise. The two stopper tabs 30 go through the narrow openings 37 and sit against the steel box side plate. In the middle area, the notches 33 (steps) are stamped out as rectangular openings. One end of the plate is bent at a 90° angle to form the two rectangular plates 31 with optional holes 35 to rest against the inside surface of the back wall 4. The plates can be in other geometric forms such as circle or triangle, etc. The tab corners in rectangular form can be also bent outward to make gripping barbs, similar to barbs 11 of part 7 in FIG. 4. The support bracket can be screwed on the wall through holes 35.

To adjust the support bracket at the necessary depth, the rectangular bent plates 31 are pushed towards the back wall all the way till they hit the back wall and the sliding part 23 stops. The latch 29 ratchets through the step holes 33 and is secured in place by the mechanism. To unlock the support bracket and slide it back, the sliding part 23 is pushed in towards the steel box 2. As the result, the spring/Stationary Base Plate 22 gets pushed down towards outlet box 2 and it stops on the side plate of the steel box 2 by the stopper tabs 30. Pushing the sliding part 28 further down pushes the spring button 28 more. Therefore the lever mechanism of the spring lifts the latch 29 backwards out of the step holes 33. To retract the assembly, the sliding part can be pulled back away form the back wall while it is held down in unlock position.

What is claimed is:

1. A universal adjustable support bracket for securing one or more electrical boxes comprising:
A stationary base plate, one end having a pair of opposed bent edges which become substantially parallel to the stationary base plate, and an offset tab on the opposing end parallel to the stationary base plate, having an attachment means for connection to one or more sides of an electrical box.
A sliding part in shape of an elongate strip of sheet metal perforated with a number of generally rectangular holes for fine adjustment, one end having opposed bent edges, as in the stationary base plate, meant for sliding securely inside the stationary base plate, and the other end with a flange directly perpendicular to the elongate strip, the perpendicular flange being generally rectangular with an optional thumb tab for retracting of pushing cut the elongate strip from the stationary base plate, and the flange's four corners being flared outwards to help found itself in the opposing wall board.
A locking or ratchet spring clip installed on the stationary base frame by clipping, welding, bolting, riveting or any other type of fastening, resting on the front surface of the stationary base frame providing pivoting points, having at least one tab used to release the locking/ratchet latch from either end of the elongate strip, consisting of two or more extended bent tabs to form the clips and a locking/ratchet latch bent at a substantially 90° angle for engaging one or more of the plurality of generally rectangular perforated holes, and having a spring mechanism comprised of at least two curved tabs for operating the ratchet spring clip.

2. A universal adjustable support bracket for securing one or more junction boxes, the bracket further comprising:
A stationary junction box clip, having jog bent edges on either side to form an indentation for an elongate strip to glide through, and those jog bent indentations having tabs extending out at an arbitrary angle with means for attachment to the side of an electrical junction box.
A sliding part in shape of an elongate strip of sheet metal, at one end having a stamped out tab with which to secure it to the stationary junction box clip, and at the other end having two tabs substantially perpendicular to the elongate strip, the elongate strip also comprising an integrated spring mechanism at an arbitrary angle between 10° to 170° for locking with the ratchet mechanism.
A flat plate of steel sheet metal, having a pair of opposed bent edges which become substantially parallel to the flat plate forming a guiding channel for the elongate stationary strip having two tabs bent at 90° with at least one hole per tab at one end and a plurality of generally rectangular perforations forming the ratchet mechanism for fine adjustment from the other end towards the middle.

3. The universal adjustable Bracket of claim 1, wherein box clip can mount on the edge, or attach to the side of the junction box through the protruding tabs into the box side holes.

4. The universal adjustable Bracket of claim 1, wherein the clip can provide a means of connecting the stationary base to the elongated strip, or the clip itself can be integrated into the elongated strip.

5. The universal adjustable Bracket of claim 1, wherein the components are made of electrically conductive material.

6. The universal adjustable Bracket of claim 1, wherein the stationary base consists of a guiding channel for the elongate strip to slide through.

7. The universal adjustable Bracket of claim 1, wherein the spring mechanism has an angled latch of arbitrary angle to engage the perforated holes of the elongate strip.

8. The universal adjustable Bracket of claim 1, wherein the tab at the end of the elongate strip bends out into one or more barbs to grip itself into the opposing wall.

9. The universal adjustable Bracket of claim 1, wherein the tab at the end of the elongate strip can be shaped as a rectangle, triangle, or any other desired shape.

10. The universal adjustable Bracket of claim 1, wherein the tab on the end of the elongate strip has a flange of any shape for pushing or pulling the elongate strip.

11. The universal adjustable Bracket of claims 1 and 2, wherein the elongate strip has an offset tab used for mounting itself upon the clip attached to the junction box.

12. The universal adjustable Bracket of claim 2, wherein the elongate strip has two substantially perpendicular tabs used for restricting the lateral movement of the Stationary Base Plate.

13. The universal adjustable Bracket of claim 2, wherein the spring mechanism is integrated into the elongate strip, and forming a pushing tab on one end and forming a ratchet latch on the other end.

14. The universal adjustable Bracket of claim 2, wherein the plurality of the generally rectangular perforated openings form the ratchet steps.

15. The universal adjustable Bracket of claim 2, wherein one or more substantially perpendicular tabs are located on the end of the sliding plate of sheet metal, having at least one hole per tab, and being of rectangular, circular, triangular, or any other geometrical origin.

16. An electrical junction box comprising said universal adjustable support bracket according to claim 1.

17. An electrical junction box comprising said universal adjustable support bracket according to claim 2.

18. An electrical junction box comprising said universal adjustable support bracket according to claim 3.

19. An electrical junction box comprising said universal adjustable support bracket according to claim 11.
